(19) United States
(12) Patent Application Publication
(10) Pub. No.: US 2019/0067758 A1
(43) Pub. Date: Feb. 28, 2019

(54) SECONDARY BATTERY DETERIORATION ASSESSMENT DEVICE

(71) Applicant: NTN CORPORATION, Osaka (JP)

(72) Inventor: Hiroyuki YAMADA, Iwata (JP)

(73) Assignee: NTN CORPORATION, Osaka (JP)

(21) Appl. No.: 16/103,395

(22) Filed: Aug. 14, 2018

Related U.S. Application Data
(63) Continuation of application No. PCT/JP2017/005983, filed on Feb. 17, 2017.

(30) Foreign Application Priority Data
Feb. 24, 2016 (JP) 2016-032945

(51) Int. Cl. H01M 10/48; G01R 31/36

(52) U.S. Cl. CPC H01M 10/482; G01R 31/3679; G01R 31/3662; H02J 7/0073; G01R 31/3689; G01R 31/3624; G01R 31/3655; G01R 31/3658

(57) ABSTRACT

This secondary battery degradation determination device includes: a plurality of voltage sensors connected to the respective batteries; a measurement current application device configured to apply measurement current containing an AC component, to each battery group; and a controller. Each voltage sensor is provided with a sensor-specific wireless communicator configured to wirelessly transmit a measurement value of voltage of the AC component. The controller receives the measurement value transmitted by each sensor-specific wireless communicator, calculates an internal resistance of each battery by use of the measurement value, and determines degradation of the battery on the basis of the internal resistance.

### CROSS REFERENCE TO THE RELATED APPLICATION

This application is a continuation application, under 35 U.S.C. § 111(a), of international application No. PCT/JP2017/005983, filed Feb. 17, 2017, which is based on and claims Convention priority to Japanese patent application No. 2016-32945, filed Feb. 24, 2016, the entire disclosure of which is herein incorporated by reference as a part of this application.

### BACKGROUND OF THE INVENTION

### Field of the Invention

The present invention relates to a deterioration assessment device or degradation determination device which assesses deterioration or determines degradation of a secondary battery that is used in an emergency power supply or the like in data centers, mobile phone base stations, or other various types of power supply devices for which stable electric power supply is required.

### Description of Related Art

In data centers, mobile phone base stations, or the like, stable supply of electric power is important. Although a commercial AC power supply is used during steady operation, such a data center, a mobile phone base station, or the like is provided with an emergency power supply in which a secondary battery is used, as an uninterruptible power supply device, for a case where the commercial AC power supply stops. Charging methods for the emergency power supply includes: a trickle charging type in which charging is carried out with a minute current by use of a charging circuit during steady operation; and a float charging type in which a load and a secondary battery are connected in parallel to a rectifier, and charging is carried out while the load is being operated with a constant current being applied. In general, the trickle charging type is more often employed in the emergency power supply.

The emergency power supply is required to have voltage and current that allow driving of a load that is driven by the commercial power supply. Since a single secondary battery (also referred to as battery) has low voltage and a small capacity, the emergency power supply is configured such that a plurality of battery groups are connected in parallel, each battery group including a plurality of batteries that are connected in series. The individual battery is a lead storage battery, a lithium ion battery, or the like.

In such an emergency power supply, the voltages of the batteries decrease due to degradation. Therefore, in order to ensure reliability, it is desired that degradation determination of each battery is performed and any battery that has been degraded is replaced. However, there has been no proposal of a device that can perform accurate degradation determination on a large number of batteries in a large-scale emergency power supply such as in a data center, a mobile phone base station, or the like.

Examples of proposals regarding conventional battery degradation determination include: a proposal of an on-vehicle battery checker that performs measurement on the entire battery (for example, Patent Document 1); a proposal in which a pulse-shaped voltage is applied to a battery and the internal impedance of the entire battery is calculated from an input voltage and a response voltage (for example, Patent Document 2); and a proposal of a method in which internal resistance of each of individual cells connected in series in a battery is measured, whereby degradation is determined (for example, Patent Document 3). As a handy checker that measures a very small resistance value such as internal resistance of a battery, an AC 4-terminal-method battery tester has been commercialized (for example, Non-Patent Document 1).

In Patent Documents 1 and 2 mentioned above, wireless data transmission is also proposed, and in addition, reduction of handling of cables and manual work, and data management by computers are also proposed.

### RELATED DOCUMENT

### Patent Document

[Patent Document 1] JP Laid-open Patent Publication No. H10-170615

[Patent Document 2] JP Laid-open Patent Publication No. 2005-100969

[Patent Document 3] JP Laid-open Patent Publication No. 2010-164441

### Non-Patent Document

[Non-Patent Document 1] AC 4-terminal-method battery tester, internal resistance measuring instrument IW7807-BP (Rev.1.7.1, Feb. 16, 2015, Tokyo Devices) (https://tokyodevices.jp/system/attachments/files/000/000/298/original/IW7807-BP-F MANUAL.pdf)

The conventional handy checker (Non-Patent Document 1) requires too many measurement positions, and thus, is not practical for an emergency power supply in which tens and hundreds of batteries are connected. Each of the technologies according to Patent Documents 1 and 2 is for performing measurement of the entirety of a power supply that include batteries, and is not for performing measurement of individual batteries, i.e., individual cells. Therefore, the accuracy of degradation determination is low, and individual batteries that have been degraded cannot be identified.

In terms of measuring the internal resistance of each of individual cells connected in series, the technology according to Patent Document 3 leads to improvement of accuracy in degradation determination, and to a technology that identifies individual batteries that have been degraded. However, the reference potential (ground level) for each voltage sensor is the potential (voltage) of the negative terminal of each cell, and thus, the reference potentials of the respective batteries in a battery group in which several tens to several hundreds of batteries are directly connected are all different. Patent Document 3 does not disclose any countermeasure for the difference in the reference potentials. In general, in order to obtain the potential of each individual cell, the potential difference is detected through differential operation, or an isolation transformer needs to be used. This results in a complicated and expensive configuration.

### SUMMARY OF THE INVENTION

An object of the present invention is to provide a secondary battery degradation determination device that is simple, that can be inexpensively produced, and that can accurately determine degradation of each of batteries in a power supply in which a plurality of battery groups are connected in parallel, each battery group including a plurality of batteries that are connected in series, each battery being a secondary battery.

Hereinafter, in order to facilitate understanding of the present invention, the present invention will be described with reference to the reference numerals used in embodiments, for the sake of convenience.

A secondary battery degradation determination device of the present invention is a secondary battery degradation determination device configured to determine degradation of each of batteries 2 in a power supply 1 in which a plurality of battery groups 3 are connected in parallel, each battery group 3 including a plurality of batteries 2 that are connected in series, each battery 2 being a secondary battery, the secondary battery degradation determination device including:

a plurality of voltage sensors 7 individually connected to the respective batteries 2;

a measurement current application device 9 configured to apply measurement current containing an AC component, to each battery group 3;

a sensor-specific wireless communicator 10 provided to each voltage sensor 7 and configured to wirelessly transmit a measurement value of voltage of the AC component that has been measured; and

a controller 11 configured to receive the measurement value transmitted by each sensor-specific wireless communicator 10, calculate an internal resistance of each battery 2 by use of the received measurement value, and determine degradation of the battery 2 on the basis of the internal resistance.

It should be noted that the AC component herein is a component the magnitude of voltage of which repeatedly changes. The direction of the voltage thereof may be always constant or the AC component may be ripple current or pulse current, for example. The “battery” may be a plurality of cells connected in series, or may be a single cell. The “controller” is not limited to a single controller, but may be divided into, for example: a main controller 11A which includes a section for receiving the measurement value; and an information processing device, such as a data server 13, which is connected via a communication means or network 12, such as LAN, to the main controller 11A and which calculates the internal resistance of each battery 2.

According to this configuration, the measurement value measured by each voltage sensor 7 is wirelessly transmitted to the controller 11. Even in a case where there are a plurality, for example, several tens to several hundreds, of batteries 2 which are connected in series and which form a battery group 3, the measurement value is wirelessly transmitted. Therefore, the reference potential (ground level) for the individual voltage sensors 7 is shared, and thus, there is no need to take the reference potential into consideration. Therefore, neither differential operation nor an isolation transformer is required. Since the measurement value measured by each of the plurality of the voltage sensors is wirelessly transmitted, no complicated wiring is necessary. Accordingly, a simple and inexpensive configuration can be realized.

Degradation is determined not for the entirety of the power supply 1 subjected to degradation determination but for each of the individual batteries 2. With respect to the determination, measurement current containing an AC component is applied, the transmitted measurement value is used to calculate the internal resistance of each battery 2, and degradation of the battery 2 is determined on the basis of the internal resistance. Thus, degradation determination can be accurately performed. The internal resistance of the battery 2 has a close relationship with the capacity of the battery 2, that is, the degree of degradation, and thus, if the internal resistance is known, degradation of the battery 2 can be accurately determined.

An effect realized by the “wireless communication” is that there is no need to take the reference potential into consideration. Since wireless communication is performed, only digital signals are transmitted and received. As a case where the voltage sensors 7 need to perform reception, since a shared current is used among a plurality of sensors, it is necessary to provide each voltage sensor 7 with information about measurement start before the current is applied (for example, information that the voltage sensor 7 should start measurement because current will be applied within several seconds, or after several seconds, or during several seconds).

In the present invention, the secondary battery degradation determination device may include a conversion section 7bc configured to convert the measurement value measured by each voltage sensor 7, into an effective value or an average value indicated in the form of a digital signal, wherein the sensor-specific wireless communicator 10 may transmit, as the measurement value, the effective value or the average value having been converted by the conversion section 7bc. Calculation of the internal resistance of the battery 2 can be accurately performed by use of the effective value or the average value. In addition, if the measurement value measured by the voltage sensor 7 is transmitted in the form of the effective value or the average value, the transmission data amount is significantly reduced when compared with a case where a signal having a voltage waveform is sent.

In the present invention, a current sensor 8 may be connected to each battery group 3, and the controller 11 may include: an internal resistance calculation section 13a configured to calculate the internal resistance of each battery 2 on the basis of the measurement value measured by a corresponding voltage sensor 7 and a measurement value measured by the current sensor 8 of the battery group 3 in which the voltage sensor 7 is provided; and a determination section 13b configured to determine degradation of the battery 2 on the basis of a calculation result of the internal resistance calculation section 13a. Even in a case where only voltage is measured, the internal resistance can be calculated with, for example, an assumption that current has a constant value. However, if the current actually flowing in the battery 2 is measured, and both the voltage and the current are obtained, the internal resistance can be more accurately calculated. Since the current flowing in the batteries arranged in series is the same, it is sufficient that one current sensor 8 is provided for each battery group 3. Alternatively, a single current sensor 8 may be provided so as to be interposed between the parallel circuit of the battery groups 3 and the charging circuit 6, for example.

In the present invention, each sensor-specific wireless communicator 10 may have a function of receiving a command and providing a corresponding voltage sensor 7 (for example, calculation processing section 7b) with an instruction that corresponds to the command, and the controller 11 may have a function of transmitting the command to each sensor-specific wireless communicator 10.

For example, the controller 11 may transmit, as the command, a measurement start command to each sensor-specific wireless communicator 10. In this case, upon receiving the measurement start command, the sensor-specific wireless communicator 10 causes the voltage sensor to start measurement. Thus, since the measurement start command is transmitted from the controller 11 to each sensor-specific wireless communicator 10, measurement timings of the respective voltage sensors 7 can be adjusted.

In this case, the controller 11 simultaneously transmits, in serial transmission or parallel transmission, a measurement start command to each voltage sensor 7, and the respective voltage sensors 7 simultaneously perform measurement after a lapse of a measurement start delay time. After the measurement has ended, the controller 11 sequentially transmits a data transmission request command to each voltage sensor 7, the voltage sensor 7 that has received the command transmits data, and this procedure is repeated, whereby data communication may be performed. In the present invention, after a certain time period from the transmission of the data transmission request command, the controller 11 may send a re-transmission request to a voltage sensor 7 from which data has not been received.

As another example, the controller 11 may simultaneously transmit, in serial transmission or parallel transmission, a measurement start command to each voltage sensor 7, and the respective voltage sensors 7 may perform measurement after a lapse of only a measurement start delay time predetermined for each voltage sensor, and may sequentially transmit measured data in an order that has been set. Thus, if each voltage sensor 7 performs measurement after a lapse of a measurement start delay time that is predetermined for the voltage sensor, even when a measurement start command is simultaneously transmitted to each sensor-specific wireless communicator 10, measurements respectively performed by a large number of voltage sensors 7 can be sequentially carried out and transmission can be carried out such that transmission is not hindered. It should be noted that a configuration may be employed in which: measurements by the respective voltage sensors 7 are simultaneously performed; a transmission delay time is set for each voltage sensor 7; and measured data are stored in a buffer or the like and are sequentially transmitted. Accordingly, similar effects to those described above can be obtained. When measurements are sequentially performed, data storage portion used when transmission is caused to wait is not necessary.

In the present invention, after a certain time period from the transmission of the measurement start command, the controller 11 may send a re-transmission request to a voltage sensor 7 from which data has not been received. There are cases where, due to some temporary transmission failure or the like, the sensor-specific wireless communicator 10 of some of the voltage sensors 7 cannot receive the measurement start command. Even in such a case, if the re-transmission request is sent, transmission can be performed, and thus, voltage measurement values of all the batteries 2 in the power supply can be obtained. Whether or not the measurement start command has been successfully received may be determined, on the controller 11 side, on the basis of whether or not a voltage measurement value has been received.

In the present invention, instead of simultaneously transmitting the measurement start command as described above, the controller 11 may individually transmit a data transmission command, such as the measurement start command, to each voltage sensor 7 (for example, sensor-specific wireless communicator 10) and may receive data sequentially. The measurement start command may be a data request command. In this configuration, no delay portion is necessary at the voltage sensor side, and the configuration at the voltage sensor side is simplified.

In the present invention, the controller 11 may include a determination section 13b configured to output an alert prepared in a plurality of stages, in accordance with a magnitude of the internal resistance that has been calculated. When an alert prepared in a plurality of stages that corresponds to the magnitude of the internal resistance is outputted, urgency of the need of battery replacement is known. Thus, without performing unnecessary battery replacement, it is possible to perform maintenance planning and preparation smoothly and quickly.

In the present invention, the measurement current application device 9 may be a discharging circuit connected in parallel to each battery group 3, the discharging circuit being a series circuit formed by a current limiting resistor 26 and a switching element 27, and the secondary battery degradation determination device may include a current application control section 11e configured to drive the switching element 27 so as to open or close such that current flowing in the discharging circuit becomes current having a pulse shape or a sine wave shape.

In this configuration, measurement current is generated by using the current applied to the circuit for charging the emergency power supply 1 subjected to degradation determination, without using a commercial power supply for measurement. Thus, the measurement current application device 9 can be simplified.

Any combination of at least two constructions, disclosed in the appended claims and/or the specification and/or the accompanying drawings should be construed as included within the scope of the present invention. In particular, any combination of two or more of the appended claims should be equally construed as included within the scope of the present invention.

### BRIEF DESCRIPTION OF THE DRAWINGS

In any event, the present invention will become more clearly understood from the following description of preferred embodiments thereof, when taken in conjunction with the accompanying drawings. However, the embodiments and the drawings are given only for the purpose of illustration and explanation, and are not to be taken as limiting the scope of the present invention in any way whatsoever, which scope is to be determined by the appended claims. In the accompanying drawings, like reference numerals are used to denote like parts throughout the several views, and:

FIG. 1 is a circuit diagram of a secondary battery degradation determination device according to a first embodiment of the present invention;

FIG. 2 is a block diagram showing a conceptual configuration of a voltage sensor and a controller in the secondary battery degradation determination device;

FIG. 3 is a flow chart showing an example of operation of the secondary battery degradation determination device;

FIG. 4 is a circuit diagram of a secondary battery degradation determination device according to another embodiment of the present invention;

FIG. 5 is a circuit diagram of a secondary battery degradation determination device according to an example of modification in which part of the another embodiment is modified; and

FIG. 6 is a circuit diagram of a secondary battery degradation determination device according to still another embodiment of the present invention.

### DESCRIPTION OF EMBODIMENTS

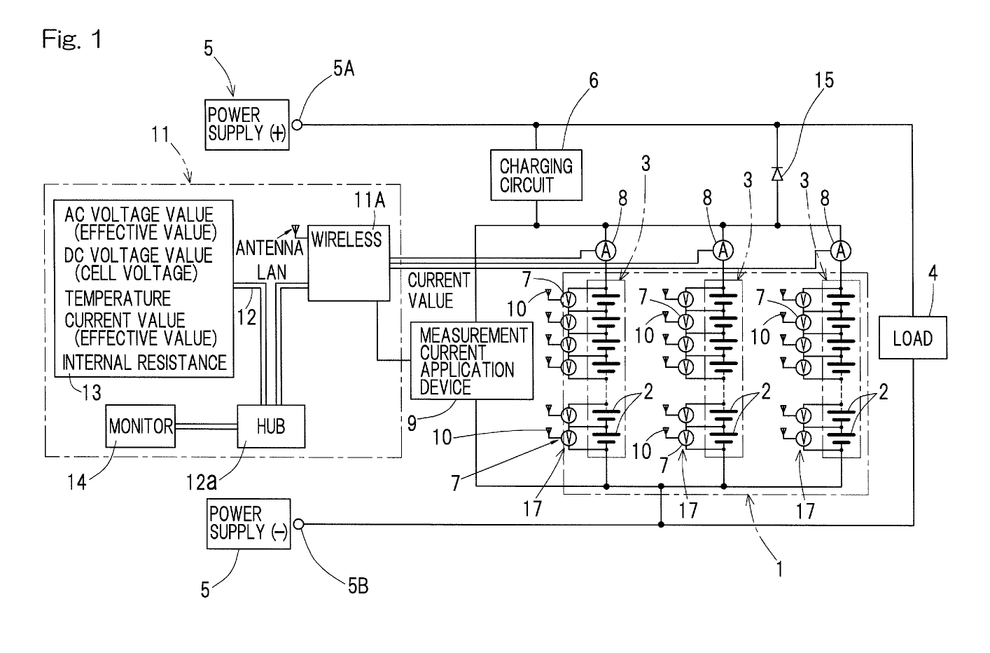

A first embodiment of a secondary battery degradation determination device of the present invention is described with reference to FIG. 1 to FIG. 3. In FIG. 1, a power supply 1 subjected to degradation determination is an emergency power supply in data centers, mobile phone base stations, or other various types of power supply devices for which stable electric power supply is required. The power supply 1 has a plurality of battery groups 3 respectively including a plurality of batteries 2 that are connected in series, each battery 2 being a secondary battery. These battery groups 3 are connected in parallel, and are connected to a load 4. Each battery 2 may be a battery that includes only one cell, or may be a battery in which a plurality of cells are connected in series.

This emergency power supply 1 is connected via a charging circuit 6 and a diode 15 to a positive terminal 5A, and is directly connected to the negative terminal 5B, of the positive and negative terminals 5A and 5B of a main power supply 5 connected to the positive and negative terminals of the load 4. The diode 15 is connected in parallel to the charging circuit 6 in the direction in which current is caused to flow from the emergency power supply 1 to the load 4. The main power supply 5 is implemented as a DC power supply or the like which is connected to, for example, a commercial AC power supply via a rectification circuit and a smoothing circuit (both not shown), and which converts AC power into DC power.

The positive potential of the emergency power supply 1 is lower than the positive potential of the main power supply 5, and does not normally cause flow to the load 4. However, when the main power supply 5 stops or the function thereof decreases, the potential at the main power supply 5 side decreases, and thus, feeding is performed via the diode 15 to the load 4 by use of electric charge stored in the emergency power supply 1. The charging type in which the charging circuit 6 is connected as described above is called a trickle charging type.

This secondary battery degradation determination device is a device that determines degradation of each battery 2 in the power supply 1. The secondary battery degradation determination device includes a plurality of voltage sensors 7 individually connected to the respective batteries 2 and a plurality of current sensors 8 respectively connected to the battery groups 3. This secondary battery degradation determination device further includes a measurement current application device 9 which applies measurement current containing an AC component, to each battery group 3 and a sensor-specific wireless communicator 10 which is provided to each voltage sensor 7 and which wirelessly transmits a measurement value of voltage of the AC component that has been measured. A controller 11 included in the secondary battery degradation determination device receives the measurement value transmitted by each sensor-specific wireless communicator 10, which calculates an internal resistance of each battery 2 by use of the received measurement value, and which determines degradation of the battery 2 on the basis of the internal resistance.

The measurement current application device 9 is implemented as a discharging device or a charging device which applies current to each battery group 3 of the power supply 1. The measurement current application device 9 is connected to the positive and negative terminal ends of each battery group 3, and provides the power supply 1 with current that has an AC component that varies with a pulse shape or a sine wave shape, such as a ripple current, for example.

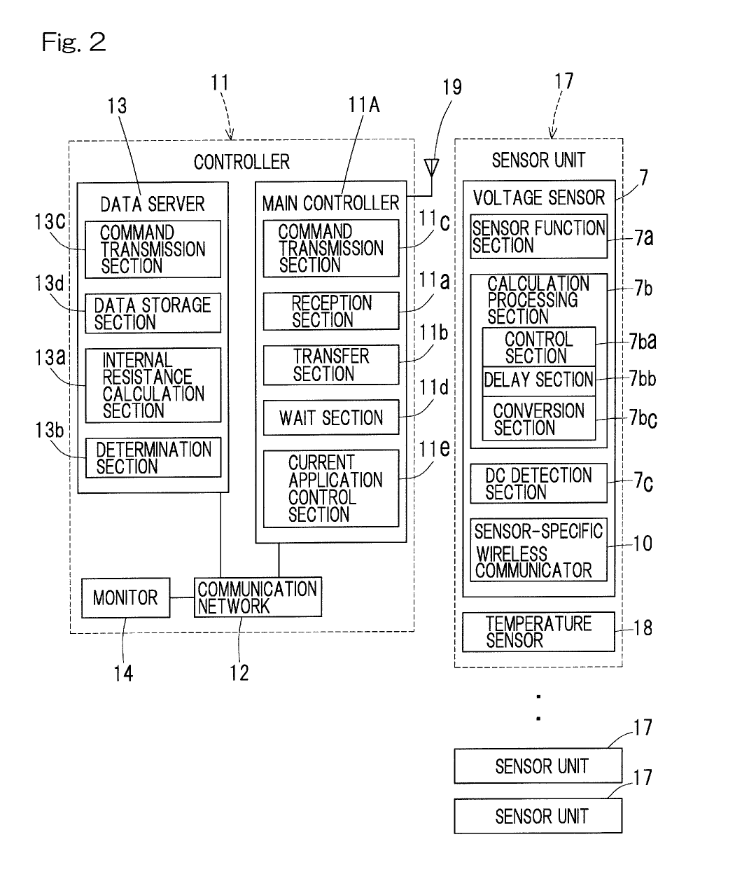

Each voltage sensor 7 detects an AC component and a DC component of voltage, and includes a sensor function section 7a and a calculation processing section 7b as shown in FIG. 2. The sensor function section 7a is implemented as a voltage detection element or the like. The calculation processing section 7b is provided with: a control section 7ba which executes a provided command (specifically, an instruction that corresponds to the command); a delay section 7bb which delays, by a predetermined time period, the start of measurement by the sensor function section 7a in response to the command; and a conversion section 7bc which converts an analog detection value of AC voltage detected by the sensor function section 7a, into an effective value or an average value in the form of a digital signal. In addition to these, the voltage sensor 7 has a DC detection section 7c which detects DC voltage, and the detection value of the DC component detected by the DC detection section 7c is also transmitted from the sensor-specific wireless communicator 10. It should be noted that the sensor function section 7a may also serve as the DC detection section 7c. The respective voltage sensors 7 have a transmission order set in advance in terms of transmission delay time by the delay section 7bb or another means, and sequentially transmit measurement values after the transmission delay time in the set order such that the measurement values are transmitted in a time multiplexed manner from the respective voltage sensors 7.

In the present embodiment, a temperature sensor 18 which measures the temperature around the battery 2 and the temperature of the battery is provided, and a sensor unit 17 is formed at least by the voltage sensor 7 and the temperature sensor 18. The detected temperature detected by the temperature sensor 18 is transmitted to the controller 11 through the sensor-specific wireless communicator 10, together with a voltage measurement value expressed as the effective value or the average value of the voltage sensor 7.

In the present embodiment, the controller 11 is formed by a main controller 11A having connected thereto a data server 13 and a monitor 14 via a communication network 12. In the present embodiment, the communication network 12 is implemented as a LAN, and has a hub 12a. The communication network 12 may be a wide area network. Through the communication network 12 and other communication networks, the data server 13 can communicate with personal computers (not shown) at remote places, and data can be monitored from any place.

The main controller 11A includes: a reception section 11a which receives a detection value detected by each voltage sensor 7 and transmitted from a corresponding sensor-specific wireless communicator 10; a transfer section llb which transfers the measurement value received by the reception section 11a, to the communication network 12; a command transmission section 11c which wirelessly transmits a command such as a transmission start to the sensor-specific wireless communicator 10 of each voltage sensor 7; a wait section 11d described later; and a current application control section 11e. The current application control section 11e controls the measurement current application device 9 (FIG. 1). In FIG. 2, wireless transmission and reception by the command transmission section 11c and the reception section 11a are carried out via an antenna 19.

As shown in FIG. 1, each current sensor 8 is connected through wiring to the main controller 11A, and the measurement value of the current is transferred together with a voltage measurement value from the transfer section 11b shown in FIG. 2. The command transmission section 11c of the main controller 11A may generate a command by itself, but in the present embodiment, in response to a measurement start command transmitted from the data server 13, the command transmission section 11c transfers the measurement start command to the sensor-specific wireless communicator 10 of each voltage sensor 7. It should be noted that the main controller 11A or each current sensor 8 is provided with a conversion section (not shown) which converts the measurement value measured by the current sensor 8 into an effective value or an average value.

As described above, the controller 11 has a function of transmitting the command to each sensor-specific wireless communicator 10, and the sensor-specific wireless communicator 10 has a function of providing, upon receiving the command, an instruction that corresponds to the command, to the calculation processing section 7b provided in the voltage sensor 7.

The data server 13 includes an internal resistance calculation section 13a and a determination section 13b. The internal resistance calculation section 13a calculates an internal resistance of the battery 2 in accordance with a predetermined calculation formula, using an AC voltage value (effective value or average value), a DC voltage value (cell voltage), a detected temperature, and a current value (effective value or average value) that have been transmitted from the main controller 11A and received by the internal resistance calculation section 13a. The detected temperature is used in temperature correction.

The determination section 13b determines that degradation has occurred when the calculated internal resistance is not less than a threshold which has been set. A plurality of the thresholds (for two to three stages, for example) are provided, degradation determination is performed in a plurality of stages, and alerts prepared in the plurality of stages are outputted as described later. The determination section 13b has a function of causing the monitor 14 to display a determination result via the communication network 12 or via dedicated wiring. In addition to the above, the data server 13 includes: a command transmission section 13c which transmits a measurement start command to the main controller 11A; and a data storage section 13d for storing data such as the voltage measurement value transmitted from the main controller 11A.

In the configuration described above, the main controller 11A and the measurement current application device 9 may be configured as an integrated controller housed in a single case. In the present embodiment, the controller 11 is configured to include the main controller 11A and the data server 13. However, the main controller 11A and the data server 13 may be configured as one controller 11 housed in a single case, or the main controller 11A and the data server 13 may be implemented, without being separated, as one information processing device formed on one board or the like.

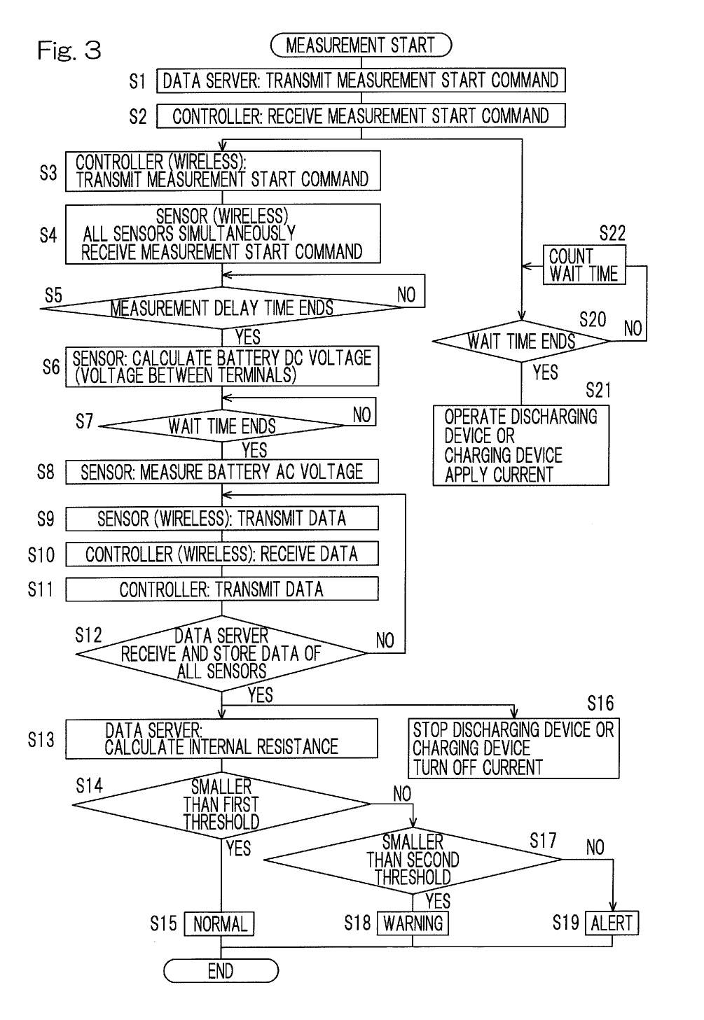

Operation of the degradation determination device having the configuration described above is described. FIG. 3 is a flow chart of one example of the operation. The data server 13 transmits a measurement start command from the command transmission section 13c (step S1). The main controller 11A receives the measurement start command from the data server 13 (step S2), and transmits the measurement start command to the sensor-specific wireless communicator 10 of each voltage sensor 7 and each current sensor 8 (step S3). In parallel with the process of this transmission and thereafter, the wait section 11d determines whether a wait time has ended (step S20) and counts the wait time (step S22). When the set wait time has ended, the measurement current application device 9 performs application of current (step S21). In this current application, discharge is started in a case where the measurement current application device 9 is a discharging device, and charge is started in a case where the measurement current application device 9 is a charging device.

The measurement start command transmitted in step S3 is received by all the voltage sensors 7 (step S4). Each voltage sensor 7 waits until its own measurement delay time ends (step S5), and measures DC voltage (voltage between terminals) of the battery 2 (step S6). Then, the voltage sensor 7 waits until the wait time ends (step S7), and measures AC voltage of the battery 2 (step S8). As for the measurement of AC voltage, a measurement value that has been directly obtained is converted into an effective voltage or an average voltage, and the converted value is outputted as a measurement value.

The measured DC voltage and AC voltage are wirelessly transmitted by the sensor-specific wireless communicator 10 after the transmission delay time for the voltage sensor 7 has elapsed (step S9), and are wirelessly received by the main controller 11A of the controller 11 (step S10). The main controller 11A transmits the received DC voltage and AC voltage to the data server 13, through the communication network 12 such as a LAN, together with detection values detected by the current sensor 8 and the temperature sensor 18 (FIG. 2) (step S11). The data server 13 receives data sequentially transmitted from sensors such as the voltage sensors 7, and stores the data in the data storage section 13d (step S12). The steps from the wireless transmission in step S9 through the data storage performed by the data server 13 are performed until reception and storage of data from all the voltage sensors 7 end (NO in step S12).

After the reception and the storage have ended (YES in step S12), an end signal indicating the end is transmitted from the data server 13 to the main controller 11A and a current application control signal is outputted from the main controller 11A, whereby current application by the measurement current application device 9 is turned off (step S16), and in the data server 13, the internal resistance of each battery 2 is calculated by the internal resistance calculation section 13a (step S13).

The determination section 13b of the data server 13 compares the calculated internal resistance with a first threshold predetermined as appropriate (step S14), and when the calculated internal resistance is smaller than the first threshold, the determination section 13b determines that the battery 2 is normal (step S15). When the calculated internal resistance is not smaller than the first threshold, the determination section 13b further compares the calculated internal resistance with a second threshold (step S17). When the calculated internal resistance is smaller than the second threshold, a warning, which is an alert for calling attention, is outputted (step S18). When the calculated internal resistance is not smaller than the second threshold, an alert, which is a stronger notification than a warning, is outputted (step S19). The alert and the warning are displayed on the monitor 14 (FIG. 1). When the battery 2 is normal, an indication that the battery 2 is normal may be displayed on the monitor 14, or may not be displayed in particular. The display of the alert and the warning on the monitor 14 may be performed by using a symbol such as a predetermined icon, or may be performed by lighting a predetermined portion, for example. In this manner, degradation determination regarding all the batteries 2 in the emergency power supply 1 is performed. FIG. 3 is an example of a two-stage degradation determination (and a two-stage display of an alert, etc.).

According to this secondary battery degradation determination device, the voltage sensors 7 are provided for the respective batteries 2, and each receive and transmit data are made in the form of a digital signal through wireless communication. Therefore, even in a case of the emergency power supply 1 that is provided with several tens to several hundreds of batteries 2, there is no need to take into consideration the electric reference potential (ground level) for each battery 2. Thus, neither differential operation nor an isolation transformer is required. In addition, since the measurement value measured by each of the plurality of the voltage sensors 7 is wirelessly transmitted, no complicated wiring is necessary. Accordingly, a simple and inexpensive configuration can be realized.

Degradation is determined not for the entirety of the power supply 1 subjected to the degradation determination but for each of the individual batteries 2. As for the determination, measurement current containing an AC component is applied, the measurement value transmitted by each sensor-specific wireless communicator 10 is used to calculate the internal resistance of each battery 2, and degradation of the battery 2 is determined on the basis of the internal resistance. Thus, the degradation determination can be accurately performed. The internal resistance of the battery 2 has a close relationship with the capacity of the battery 2, that is, the degree of degradation, and thus, if the internal resistance is known, degradation of the battery 2 can be accurately determined.

The measurement value measured by each voltage sensor 7 is converted into an effective value or an average value indicated as a digital signal, and the digital signal is transmitted. Therefore, compared with a case where a signal having a voltage waveform is sent, the transmission data amount is significantly reduced. Calculation of the internal resistance of the battery 2 can be accurately performed by use of the effective value or the average value. Even in a case where only voltage is measured, the internal resistance of the battery 2 can be calculated with, for example, an assumption that current has a constant value. However, if the current actually flowing in the battery 2 is measured and both the voltage and the current are obtained, the internal resistance can be more accurately calculated. Since the current flowing in the batteries 2 arranged in series is the same, it is sufficient that one current sensor 8 is provided for each battery group 3.

The controller 11 transmits a measurement start command to the sensor-specific wireless communicator 10 of each voltage sensor 7, and this command causes measurement of the voltage sensor 7 to start. Accordingly, measurement start timings of the voltage sensors 7 that exist by a large number can be adjusted. In this case, the controller 11 simultaneously transmits, in serial transmission or parallel transmission, the measurement start command to each voltage sensor 7, and each voltage sensor 7 simultaneously performs measurement after a lapse of a measurement start delay time. After the measurement has ended, the controller 11 sequentially transmits a data transmission request command to each voltage sensor 7, the voltage sensor 7 that has received the command transmits data, and this procedure is repeated, whereby data communication may be performed. In the present embodiment, after a certain time period from the transmission of the data transmission request command, the controller 11 may send a re-transmission request to a voltage sensor 7 from which data has not been received.

As another example, in a case where measurement is performed after a lapse of only a measurement start delay time that is predetermined for each voltage sensor 7, even when a measurement start command is simultaneously transmitted to each sensor-specific wireless communicator 10, measurements respectively performed by the large number of voltage sensors 7 can be sequentially carried out and transmission can be carried out such that wireless transmission and reception are not hindered. For example, a transmission start command is a global command, and is simultaneously obtained by each voltage sensor 7.

After a certain time period from the transmission of the measurement start command, the controller 11 sends a re-transmission request to a voltage sensor 7 from which data has not been received. There are cases where, due to some temporary transmission failure or the like, the sensor-specific wireless communicator 10 of some of the voltage sensors 7 cannot receive the measurement start command. Even in such a case, if the re-transmission request is sent, voltage can be measured and transmitted, and thus, voltage measurement values of all the batteries 2 in the power supply can be obtained. Whether or not the measurement start command has been successfully received may be determined, on the controller 11 side, on the basis of whether or not a voltage measurement value has been received.

Instead of simultaneously transmitting the measurement start command as described above, the controller 11 may individually transmit a data request command to the sensor-specific wireless communicator 10 of each voltage sensor 7, and may receive data sequentially. In this configuration, the delay section 7bb at the voltage sensor 7 side is not necessary, and the configuration at the voltage sensor 7 side is simplified. Since the controller 11 outputs an alert prepared in a plurality of stages, in accordance with the magnitude of the calculated internal resistance, urgency of the need of battery replacement is known. Thus, without performing unnecessary battery replacement, it is possible to perform maintenance planning and preparation smoothly and quickly.

Specifically, the controller 11 and components therein are configured by software functions on a processor (not shown) or hardware circuits that can output results by performing calculation using: LUTs (look up table) realized by software or hardware; or predetermined transform functions stored in a software library, hardware equivalent thereto, or the like; and, if necessary, comparison functions, arithmetic operation functions in a library, hardware equivalent thereto, or the like.

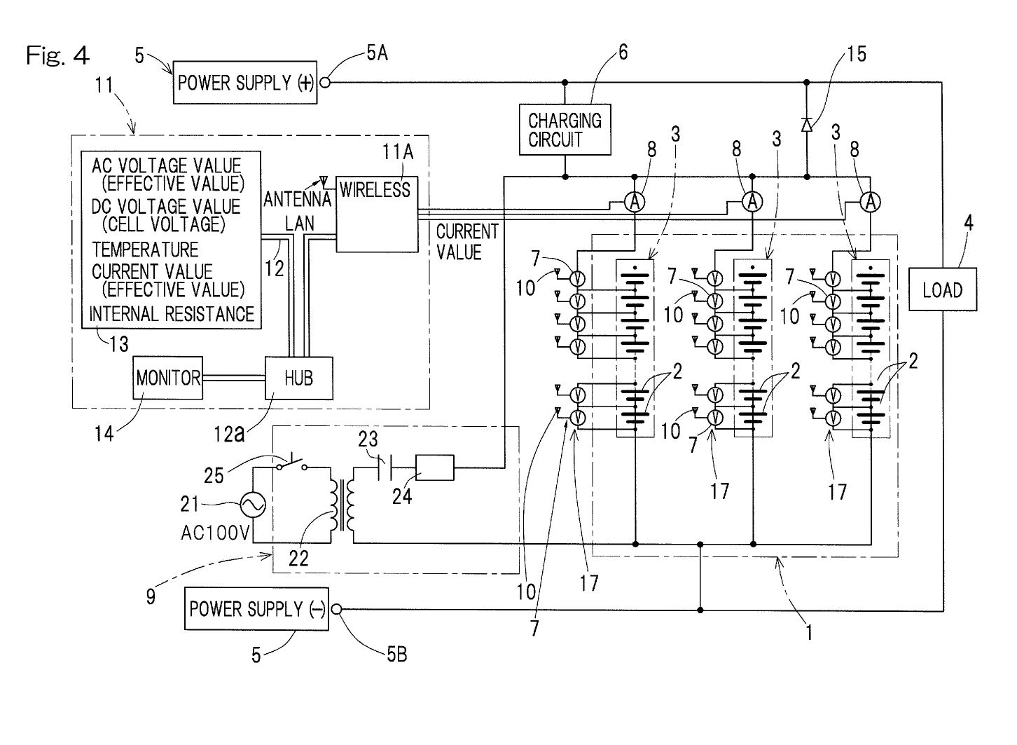

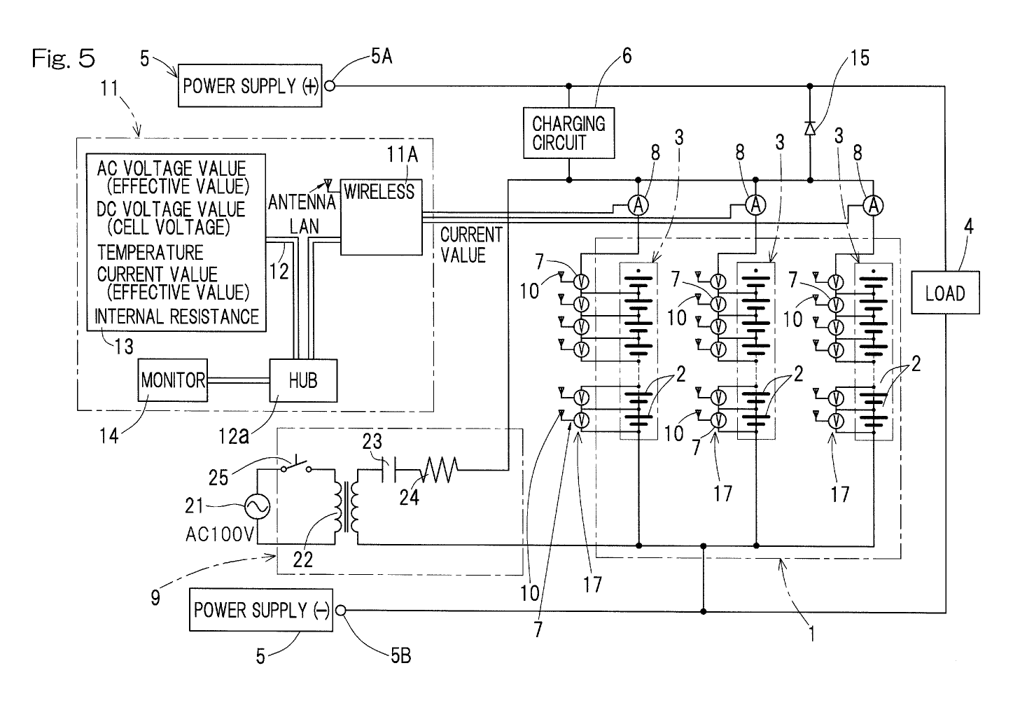

FIG. 4 shows another embodiment obtained by embodying the measurement current application device 9 in the above embodiment shown in FIG. 1 to FIG. 3. In the present embodiment, the measurement current application device 9 generates measurement current containing an AC component from a commercial AC power supply 21, and applies the generated measurement current to each battery group 3. More specifically, the measurement current application device 9 includes: a transformer 22 which converts voltage such that the voltage of the commercial AC power supply 21 suits the voltage of the emergency power supply 1; a capacitor 23 (secondary side) which separates only the AC component from the current converted by the transformer 22 and applies the AC component to each battery group 3; and a current limiting section 24 (secondary side) which limits current to be applied to each battery group 3. The primary circuit of the transformer 22 is provided with an open/close switch 25 which turns off/on the commercial power supply 21. Opening/closing of the open/close switch 25 is controlled by the current application control section 11e (see FIG. 2) in the main controller 11A of the controller 11. In FIG. 4, the current limiting section 24 may be a resistor as shown in FIG. 5, that is, a current limiting resistor.

In this configuration, measurement current containing the AC component is generated from the commercial AC power supply 21, and thus, in a simple configuration, the measurement current containing the AC component can be applied to each battery group 3. Since the transformer 22 and the capacitor 23 are provided, even when the voltages of the commercial power supply 21 and each battery group 3 are different from each other, the voltage accompanied with the measurement current can be made to match the voltage of the battery group 3, and only the AC component can be applied to the battery group 3. Since the current limiting section 24 such as a resistor is provided, the current that is applied to each battery group 3 can be limited, and thus, the battery group 3 can be protected from overcurrent. The other configurations and effects in the present embodiment are the same as those in the first embodiment described above with reference to FIG. 1 to FIG. 3.

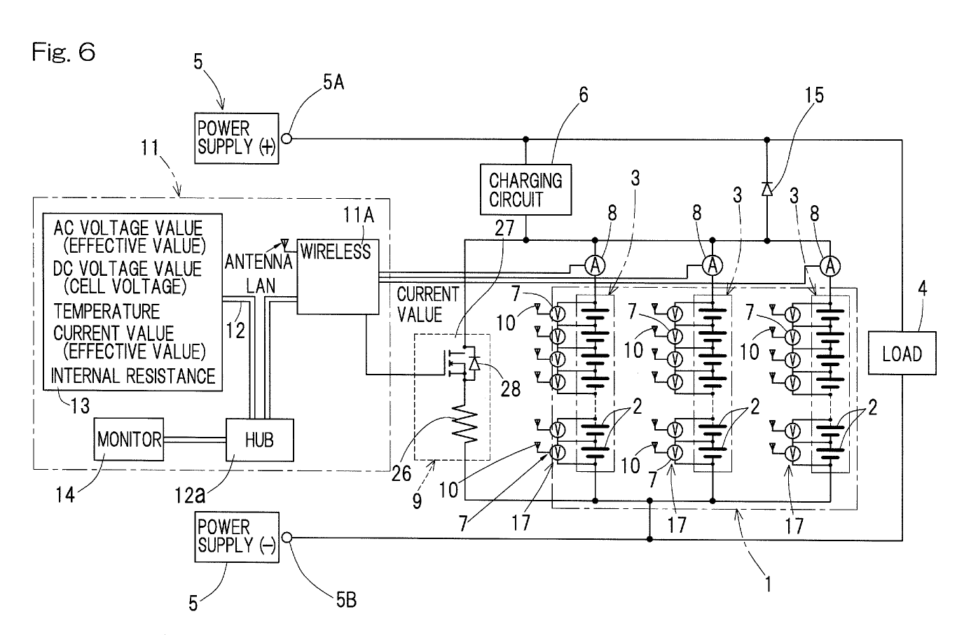

FIG. 6 shows still another embodiment of the present invention. In the present embodiment, the measurement current application device 9 in the first embodiment shown in FIG. 1 to FIG. 3 is configured as a discharging circuit formed as a series circuit of a current limiting resistor 26 and a switching element 27, and this discharging circuit is connected in parallel to each battery group 3. The switching element 27 is provided with a diode 28 for providing bypass. The switching element 27 is driven to open or close by the current application control section 11e in the main controller 11A of the controller 11 such that the current flowing in the discharging circuit becomes current having a pulse shape or a sine wave shape. In this case, different from the example shown in FIG. 4, the current application control section 11e is configured to provide an instruction for driving the switching element 27 so as to realize current having a pulse shape or a sine wave shape.

In this configuration, measurement current is generated by using the current applied to the circuit for charging the emergency power supply 1 subjected to degradation determination, without using a commercial power supply for measurement. Thus, compared with the embodiment that uses a commercial power supply shown in FIG. 4, the measurement current application device 9 can be simplified. The other configurations and effects are the same as those in the first embodiment shown in FIG. 1 to FIG. 3.

Although the present invention has been fully described in connection with the preferred embodiments thereof with reference to the accompanying drawings which are used only for the purpose of illustration, those skilled in the art will readily conceive numerous changes and modifications within the framework of obviousness upon the reading of the specification herein presented of the present invention. Accordingly, such changes and modifications are, unless they depart from the scope of the present invention as delivered from the claims annexed hereto, to be construed as included therein.

### REFERENCE NUMERALS

1 . . . power supply

2 . . . battery

3 . . . battery group

4 . . . load

5 . . . main power supply

5A, 5B . . . terminal

6 . . . charging circuit

7a . . . sensor function section

7b . . . calculation processing section

7ba . . . control section

7bb . . . delay section

7bc . . . conversion section

7c . . . DC detection section

8 . . . current sensor

9 . . . measurement current application device

10 . . . sensor-specific wireless communicator

11 . . . controller

11A . . . main controller

11a . . . reception section

11b . . . transfer section

11c . . . command transmission section

11d . . . wait section

11e . . . current application control section

12 . . . communication network

13 . . . data server

13a . . . internal resistance calculation section

13b . . . determination section

14 . . . monitor

15 . . . diode

17 . . . sensor unit

18 . . . temperature sensor

19 . . . antenna

21 . . . commercial power supply

22 . . . transformer

23 . . . capacitor

24 . . . current limiting section

25 . . . open/close switch

26 . . . current limiting resistor

27 . . . switching element

What is claimed is:

1. A secondary battery degradation determination device configured to determine degradation of each of batteries in a power supply in which a plurality of battery groups are connected in parallel, each battery group including a plurality of batteries that are connected in series, each battery being a secondary battery, the secondary battery degradation determination device comprising:
a plurality of voltage sensors individually connected to the respective batteries;
a measurement current application device configured to apply measurement current containing an AC component, to each battery group;
a sensor-specific wireless communicator provided to each voltage sensor and configured to wirelessly transmit a measurement value of voltage of the AC component that has been measured; and
a controller configured to receive the measurement value transmitted by each sensor-specific wireless communicator, calculate an internal resistance of each battery by use of the received measurement value, and determine degradation of the battery on the basis of the internal resistance.

2. The secondary battery degradation determination device as claimed in claim 1, comprising
a conversion section configured to convert the measurement value measured by each voltage sensor, into an effective value or an average value indicated in the form of a digital signal, wherein
the sensor-specific wireless communicator transmits, as the measurement value, the effective value or the average value having been converted by the conversion section.

3. The secondary battery degradation determination device as claimed in claim 1, wherein
a current sensor is connected to each battery group, and
the controller includes:
an internal resistance calculation section configured to calculate the internal resistance of each battery on the basis of the measurement value measured by a corresponding voltage sensor and a measurement value measured by the current sensor of the battery group in which the voltage sensor is provided; and
a determination section configured to determine degradation of the battery on the basis of a calculation result of the internal resistance calculation section.

4. The secondary battery degradation determination device as claimed in claim 1, wherein
each sensor-specific wireless communicator has a function of receiving a command and providing a corresponding voltage sensor with an instruction that corresponds to the command, and
the controller has a function of transmitting the command to each sensor-specific wireless communicator.

5. The secondary battery degradation determination device as claimed in claim 4, wherein
the controller transmits, as the command, a measurement start command to each sensor-specific wireless communicator.

6. The secondary battery degradation determination device as claimed in claim 4, wherein
the controller simultaneously transmits, in serial transmission or parallel transmission, a measurement start command to each voltage sensor, and
the respective voltage sensors perform measurement after a lapse of only a predetermined measurement start delay time, and sequentially transmit measured data in an order that has been set.

7. The secondary battery degradation determination device as claimed in claim 5, wherein
after a certain time period from the transmission of the measurement start command, the controller sends a re-transmission request to a voltage sensor from which data has not been received.

8. The secondary battery degradation determination device as claimed in claim 4, wherein
the controller individually transmits a data transmission command to each voltage sensor and receives data sequentially.

9. The secondary battery degradation determination device as claimed in claim 1, wherein
the controller includes a determination section configured to output an alert prepared in a plurality of stages, in accordance with a magnitude of the internal resistance that has been calculated.

10. The secondary battery degradation determination device as claimed in claim 1, wherein
the measurement current application device is a discharging circuit connected in parallel to each battery group, the discharging circuit being a series circuit formed by a current limiting resistor and a switching element, and
the secondary battery degradation determination device comprises a current application control section configured to drive the switching element so as to open or close such that current flowing in the discharging circuit becomes current having a pulse shape or a sine wave shape.
